(19) United States
(12) Patent Application Publication
(10) Pub. No.: US 2015/0333285 A1
(43) Pub. Date: Nov. 19, 2015

(54) DISPLAY DEVICE

(71) Applicant: PANASONIC CORPORATION, Osaka (JP)

(72) Inventor: Shinya OGASAWARA, Hyogo (JP)

(73) Assignee: PANASONIC CORPORATION, Osaka (JP)

(21) Appl. No.: 14/410,012

(22) PCT Filed: Sep. 30, 2013
(86) PCT No.: PCT/JP2013/005804

§ 371 Date: Dec. 19, 2014

(30) Foreign Application Priority Data
Oct. 1, 2012 (JP) 2012-219114

(51) Int. Cl. H01L 51/52; H01L 27/32; H05K 5/02

(52) U.S. Cl. CPC H01L 51/524; H05K 5/0243; H01L 27/322; H01L 27/3244; H01L 51/529; H01L 51/5262

(57) ABSTRACT

A display device includes a back cover, an image display panel, a chassis disposed between the back cover and the image display panel, an escutcheon to cover the periphery of the image display panel, and a plurality of holding members. Each of the plurality of the holding members is coupled with the chassis. Moreover, the each of the plurality of the holding members is coupled with the escutcheon. Furthermore, at least a part of the plurality of the holding members is coupled with the back cover. The image display panel is configured such that the periphery of the image display panel is pushed by the escutcheon in the direction toward the chassis.

### TECHNICAL FIELD

The technology disclosed herein relates to display devices equipped with organic EL (Electro-Luminescence) panels or the like.

### BACKGROUND ART

In a plasma display device, i.e. a display device, technologies have been known which allow easy separation and disassembling of a panel from a chassis (see Patent Literature 1, for example).

### CITATION LIST

### Patent Literature

Patent Literature 1: Japanese Patent Unexamined Publication No. 2002-221914

### SUMMARY OF THE INVENTION

A display device disclosed herein includes a back cover, an image display panel, a chassis disposed between the back cover and the image display panel, an escutcheon to cover the periphery of the image display panel, and a plurality of holding members. Each of the plurality of the holding members is coupled with the chassis. Moreover, the each of the plurality of the holding members is coupled with the escutcheon. Furthermore, at least a part of the plurality of the holding members is coupled with the back cover. The image display panel is configured such that the periphery of the image display panel is pushed by the escutcheon in the direction toward the chassis.

### BRIEF DESCRIPTION OF DRAWINGS

FIG. 1 is a schematic exploded perspective view illustrating a configuration of an organic EL panel.

FIG. 2 is a view of a part of a cross section taken along line 2-2 in FIG. 1.

FIG. 3 is a view of a part of a cross section taken along line 3-3 in FIG. 10

FIG. 4 is a partially cut-away perspective view of an organic EL display device, as viewed from a back cover side.

FIG. 5 is a schematic view of a part of a cross section taken along line 5-5 in FIG. 4.

FIG. 6 is an enlarged view of the cut-away portion in FIG. 4.

FIG. 7 is a schematic exploded perspective view illustrating a configuration of the organic EL display device.

FIG. 8 is a view illustrating steps of assembling the organic EL display device.

FIG. 9 is a view of the organic EL display device, as viewed from a display screen side.

FIG. 10 is a view of a part of a cross section taken along line 10-10 in FIG. 9.

FIG. 11 is a view of an exemplary modification of the embodiment.

FIG. 12 is a view illustrating a shape of a holding member which is disposed at each of the two long and two short sides of the display device.

FIG. 13 is a view indicating corner portions of the organic EL display device.

FIG. 14 is a view illustrating a shape of a holding member which is disposed at each of the corner portions of the display device.

### DESCRIPTION OF EMBODIMENTS

Hereinafter, detailed descriptions of embodiments will be made with reference to the accompanying drawings as deemed appropriate. However, descriptions in more detail than necessary will sometimes be omitted. For example, detailed descriptions of well-known items and duplicate descriptions of substantially the same configuration will sometimes be omitted, for the sake of brevity and easy understanding by those skilled in the art.

It is noted that the present inventors provide the accompanying drawings and the following descriptions so as to facilitate fully understanding of the present disclosure by those skilled in the art. The inventors in no way intend for the present disclosure to impose any limitation on the subject matter described in the appended claims.

Conventionally, a chassis included in a display device is equipped with an escutcheon, a back cover, and the like which are attached with screws or the like. The chassis has bosses to which they are attached with the screws. Therefore, the chassis is required to have a thickness enough to press-fit the bosses into the chassis. Moreover, the chassis is required to have a mechanical strength enough to fix the escutcheon and the back cover. Furthermore, the escutcheon disposed in the display device has bosses to which the parts are attached with the screws. In such the conventional display device, there have been problems in that the thickness of the display device is difficult to be made smaller without reducing the mechanical strength of the chassis, and in that a frame occupying an area outside of the display area is difficult to be made smaller.

### 1. Configuration of Organic EL Display Panel 10

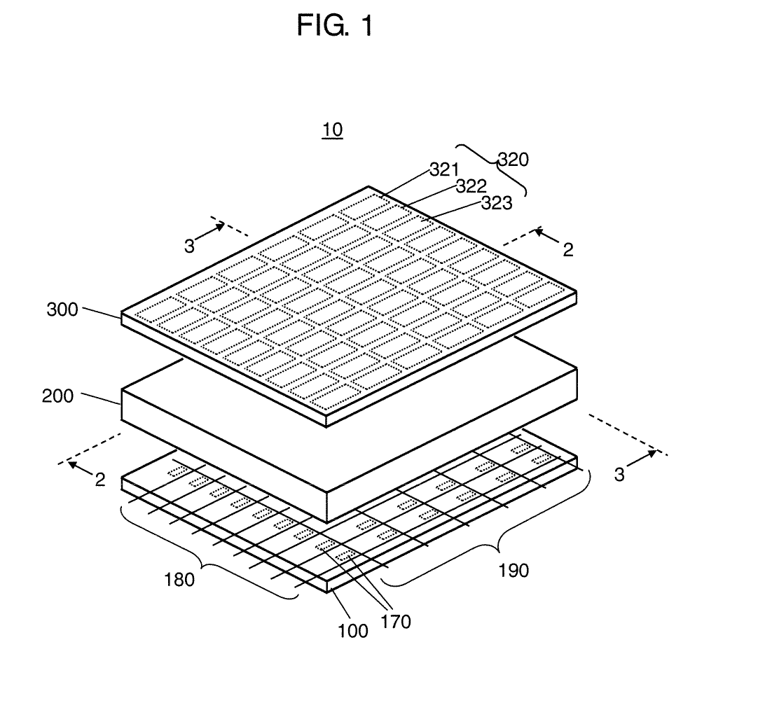

As shown in FIGS. 1 to 3, organic EL panel 10 disclosed herein is configured such that there are laminated TFT substrate 100, EL device part 200, and color filter substrate 300. EL device part 200 and color filter substrate 300 are bonded to each other with bonding layer 20.

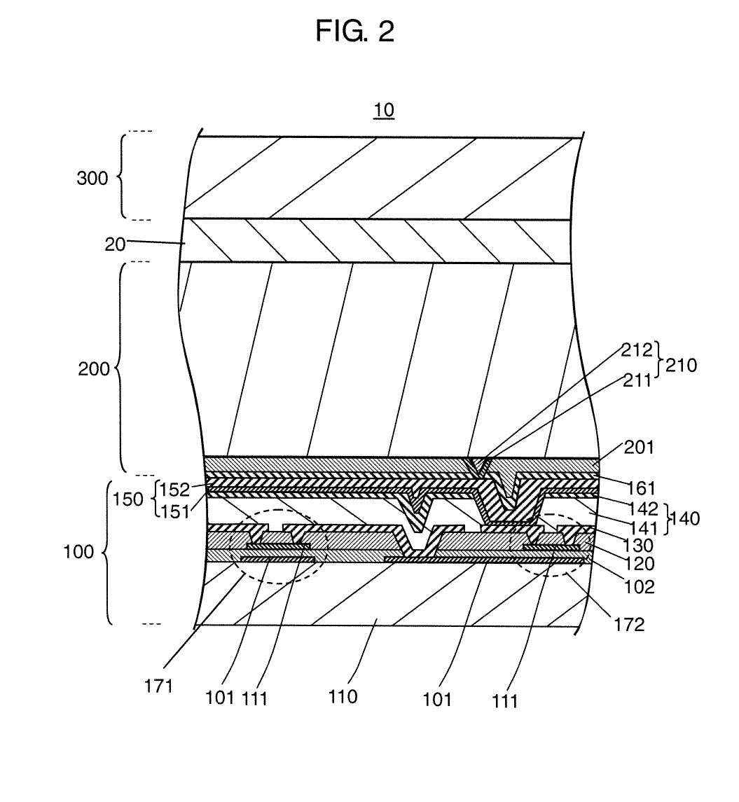

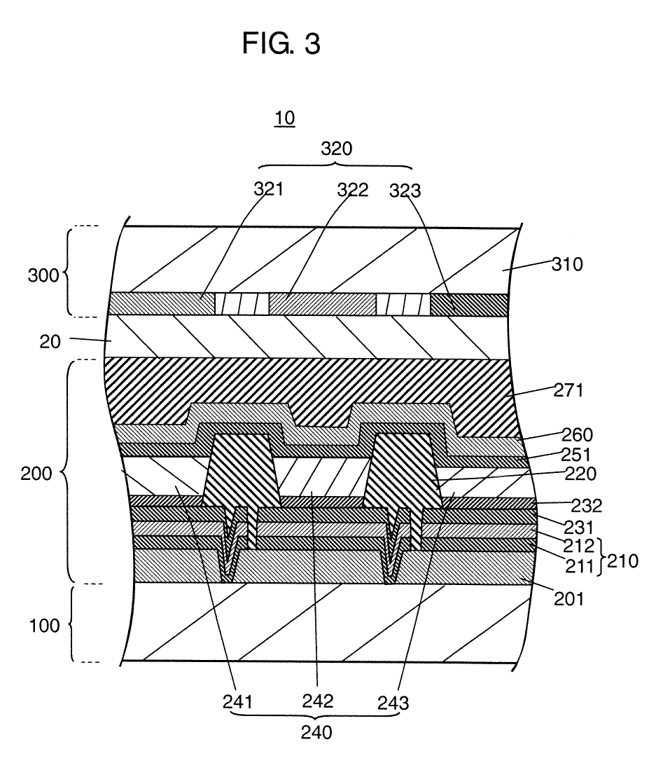

It is noted that, in FIG. 2, the configurations of EL device part 200 and color filter substrate 300 are appropriately omitted. In FIG. 3, the configuration of TFT substrate 100 is appropriately omitted.

As shown in FIG. 1, TFT substrate 100 includes a plurality of TFT parts 170. Each of TFT parts 170 includes at least two TFTs, as described later. The plurality of TFT parts 170 is arranged in a matrix pattern. Moreover, the each of TFT parts 170 is fed with a signal via gate wiring 180 and source wiring 190.

As shown in FIG. 3, EL device part 200 includes light emitting layer 240. Light emitting layer 240 emits light through recombination of holes injected from anode 210 and electrons injected from cathode 260.

As shown in FIGS. 1 and 3, color filter substrate 300 includes filter 320 that is disposed on glass substrate 310. Filter 320 includes red color filter 321, green color filter 322, and blue color filter 323. Red color filter 321 transmits red light emitted from EL device part 200; green color filter 322 transmits green light emitted from EL device part 200; blue color filter 323 transmits blue light emitted from EL device part 200. That is, organic EL panel 10 disclosed herein is of a top-emission type.

In an organic EL display device of a bottom-emission type, light is emitted from the TFT substrate side. On the other hand, in the top-emission type device, the TFT substrate is not disposed on the side from which the light is emitted. Therefore, the top-emission type device can be made to have a higher aperture ratio than the bottom-emission type device. That is, the top-emission type device has an increased luminous efficiency.

### 1-1. Configuration of TFT Substrate 100

As shown in FIGS. 1 and 2, TFT substrate 100 includes the plurality of TFT parts 170 on glass substrate 110. Each of TFT parts 170 includes switching TFT 171 and driving TFT 172. Switching TFT 171 switches ON/OFF of driving TFT 172. Driving TFT 172 controls electric current supplied to EL device part 200.

Gate electrode 101 is coupled with gate wiring 180. First electrode 130 is coupled with source wiring 190.

When a gate signal is inputted to gate wiring 180, switching TFT 171 is turned ON. Then, electric charge supplied via source wiring 190 is accumulated in a capacitor (not shown). The charge accumulated in the capacitor (not shown) causes continuous variations in electrical conductance of driving TFT 172. Accordingly, a driving current can be passed through EL device part 200, which thereby causes EL device part 200 to emit light with a desired luminance.

TFT part 170 disclosed herein is of a bottom-gate type. Gate electrode 101 is covered with gate oxide film 102. A part of gate oxide film 102 is opened to transmit a signal therethrough to gate electrode 101 of driving TFT 172.

On gate oxide film 102, semiconductor layer 111 is disposed. Semiconductor layer 111 is covered with first insulating layer 120. First insulating layer 120 is SiO2, as an example. A part of first insulating layer 120 is opened. Through this opening, first electrode 130 is coupled with semiconductor layer 111. In FIG. 2, first electrode 130 coupled with the right side (the drain side) of switching TFT 171 as viewed facing the sheet of the Figure, is coupled with gate electrode 101 of driving TFT 172.

First electrode 130 is covered with protective layer 140. Protective layer 140 has a laminated structure of first protective layer 141 and second protective layer 142. First protective layer 141 is a silicon oxide film, as an example. Second protective layer 142 is a silicon nitride film, as an example. A part of protective layer 140 is opened to receive a signal from driving TFT 172.

On protective layer 140, second electrode 150 is disposed. Second electrode 150 has a laminated structure of lower-layer electrode 151 and upper-layer electrode 152, as an example. In FIG. 2, second electrode 150 is coupled with first electrode 130 on the left side (the source side) of driving TFT 172 as viewed facing the sheet of the Figure. Lower-layer electrode 151 is composed of ITO (Indium Tin Oxide), as an example. Upper-layer electrode 152 is composed of Cu, as an example.

Second electrode 150 is covered with second insulating layer 161. A part of second insulating layer 161 is opened.

### 1-2. Configuration of EL Device Part 200

### 1-2-1. Planarization Layer 201

As shown in FIG. 3, EL device part 200 is coupled with TFT substrate 100 via regions where parts of planarization layer 201 are opened. Specifically, anode 210 configured with upper-layer anode 212 and lower-layer anode 211 is coupled with TFT substrate 100. Planarization layer 201 is disposed on TFT substrate 100. That is, planarization layer 201 reduces the surface unevenness appearing in TFT substrate 100. Planarization layer 201 is composed of a resin, as an example.

### 1-2-2. Anode 210

Anode 210 covers planarization layer 201. The regions where planarization layer 201 is opened are filled with parts of anode 210. Anode 210 has a laminated structure of lower-layer anode 211 and upper-layer anode 212, as an example. Lower-layer anode 211 is composed of an aluminum alloy, as an example. Upper-layer anode 212 is composed of IZO (Indium Zinc Oxide), as an example. Anode 210 has a function of reflecting light emitted from light emitting layer 240. This is intended to provide a higher luminous efficiency for the organic EL display device of the top-emission type.

### 1-2-3. Hole Injection Layer 231

Hole injection layer 231 covers anode 210. Hole injection layer 231 injects holes into light emitting layer 240. The ionization energy of hole injection layer 231 is chosen to be between the work function of anode 210 and the ionization energy of light emitting layer 240.

### 1-2-4. Electron Blocking Layer 232

Electron blocking layer 232 covers hole injection layer 231. Electron blocking layer 232 inhibits electrons from reaching hole injection layer 231, with the electrons being injected by electron injection layer 251 to be described later. The ionization energy of electron blocking layer 232 is larger than that of light emitting layer 240.

### 1-2-5. Light Emitting Layer 240

Light emitting layer 240 includes red-light emitting layer 241 that emits red light, green-light emitting layer 242 that emits green light, and blue-light emitting layer 243 that emits blue light, as an example. As shown in FIG. 3, each of red-light emitting layer 241, green-light emitting layer 242, and blue-light emitting layer 243 is disposed in a region partitioned by banks 220. Light emitting layer 240 is interposed between electron blocking layer 232 and electron injection layer 251 to be described later.

Light emitting layer 240 is a layer which provides sites for electrons to recombine with holes. Light emitting layer 240 includes a host and a dopant which functions as a luminescent center when the electrons recombine with the holes.

### 1-2-6. Electron Injection Layer 251

Electron injection layer 251 covers light emitting layer 240 and banks 220. Electron injection layer 251 injects electrons into light emitting layer 240. The electron affinity of electron injection layer 251 is chosen to be between the work function of cathode 260 to be described later and the electron affinity of light emitting layer 240.

### 1-2-7. Cathode 260

Cathode 260 covers electron injection layer 251. In the organic EL display device of the top-emission type, it is desired to increase the visible light transmittance of the electrodes on the display screen side. Cathode 260 is composed of a transparent and electrically-conductive material or the like, such as ITO or IZO, for example.

### 1-2-8. Sealing Layer 271

Sealing layer 271 covers cathode 260. Unsealed EL device part 200 is vulnerable to moisture intrusion into the inside of EL device part 200, with the moisture coming from water in the environment and in cleaning processes. The moisture intrusion sometimes causes peeling of the layers, which results in the tendency for the EL device part to have a defect that no normal light emission is obtained. For this reason, sealing layer 271 is preferably disposed.

### 1-3. Color Filter Substrate 300

Color filter substrate 300 changes the luminous color by utilizing absorption of the light. That is, color filter substrate 300 increases the color purity of the light by transmitting the light through it. Filter 320 adjusts the wavelength of the transmitted light, through the use of pigments or the like.

### 2. Structure of Organic EL Display Device 500

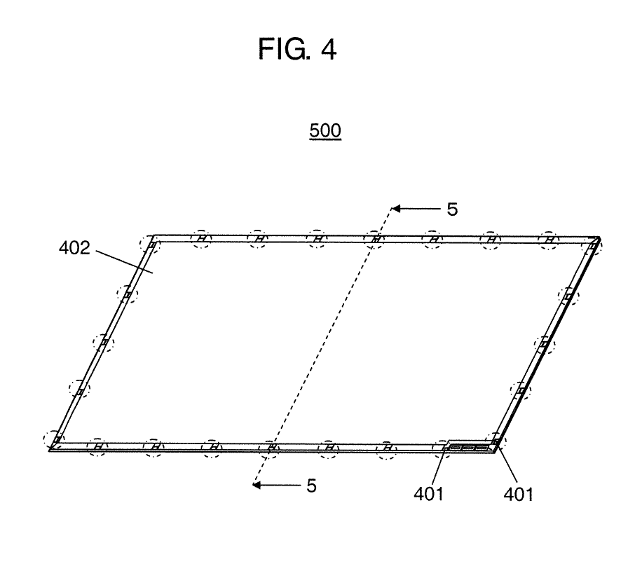

As shown in FIGS. 4 to 6, organic EL display device 500 disclosed herein includes back cover 402, organic EL display panel 10 serving as an image display panel, chassis 404 disposed between back cover 402 and organic EL display panel 10, escutcheon 403 to cover the periphery of organic EL display panel 10, and a plurality of holding members 401.

Holding members 401 are disposed at positions indicated by the dot-dash line circles in FIG. 4. That is, in organic EL display device 500 disclosed herein, holding members 401 are disposed at 24 positions. In FIG. 4, holding members 401 are illustrated as visible for convenience of explanation; however, holding members 401 are not visible in the actual product, because of being covered with back cover 402.

At least a part of the plurality of holding members 401 is coupled with chassis 404. Moreover, each of the plurality of holding members 401 is coupled with escutcheon 403. Furthermore, the each of the plurality of holding members 401 is coupled with back cover 402. It is noted, however, that the each of the plurality of holding members 401 may be coupled with chassis 404.

Organic EL display panel 10 is configured such that the periphery of organic EL display panel 10 is pushed by escutcheon 403 in the direction toward chassis 404. Organic EL display panel 10 is not bonded to chassis 404.

For holding members 401, a material such as a resin or a metal is used, for example. Specifically, aluminum-alloy molded articles or the like are used. For back cover 402, a material such as a resin or a metal is used, for example. Specifically, an aluminum-alloy molded article or the like is used. For escutcheon 403, a material such as a resin is used, for example. Specifically, a polypropylene resin or the like is used. For chassis 404, a material such as a metal plate is used, for example. Specifically, an aluminum plate or the like is used.

Holding members 401 are coupled with chassis 404 with screws, as an example. Holding members 401 are coupled with escutcheon 403 with screws, adhesive, or the like, for example. Holding members 401 are coupled with back cover 402 with screws, as an example.

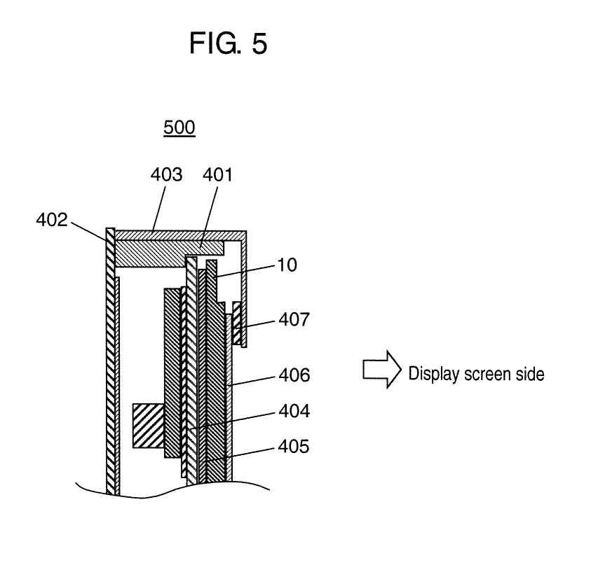

As shown in FIG. 5, organic EL display panel 10 may include heat radiation sheet 405 on the chassis 404 side of the panel. This is intended to facilitate the diffusion of heat generated from organic EL display panel 10. Heat radiation sheet 405 is fixed to organic EL display panel 10 with adhesive or the like, for example. For heat radiation sheet 405, a material such as an aluminum sheet is used, as an example.

It is noted, however, that organic EL display panel 10 may or may not be bonded to chassis 404. When organic EL display device 500 includes heat radiation sheet 405, heat radiation sheet 405 may or may not be bonded to chassis 404.

Moreover, organic EL display device 500 may further include antireflection sheet 406 between escutcheon 403 and organic EL display panel 10, with the antireflection sheet covering the display area of organic EL display panel 10. This configuration is because the suppression of reflection of light incident from the outside increases the display image quality. Antireflection sheet 406 is fixed to organic EL display panel 10 with adhesive, for example.

As shown in FIG. 5, escutcheon 403 may include cushion 407. For cushion 407, a sponge material is used, as an example. Via cushion 407, organic EL display panel 10 can be pushed. That is, it is possible to prevent organic EL display panel 10 from being subjected to localized loads, resulting in a reduced possibility of breakages of organic EL display panel 10.

Moreover, organic EL display panel 10 may be of a curved shape such that the center portion of the panel is curved toward the chassis 404 side, as viewed from the display screen side. This shape allows to improve a contact between organic EL display panel 10 and chassis 404. The thus-improved contact between them results in the greater ease of heat radiation from organic EL display panel 10.

It is noted, however, that the view of FIG. 5 is different from the actual product in terms of horizontal and vertical reduction scales, for convenience of explanation.

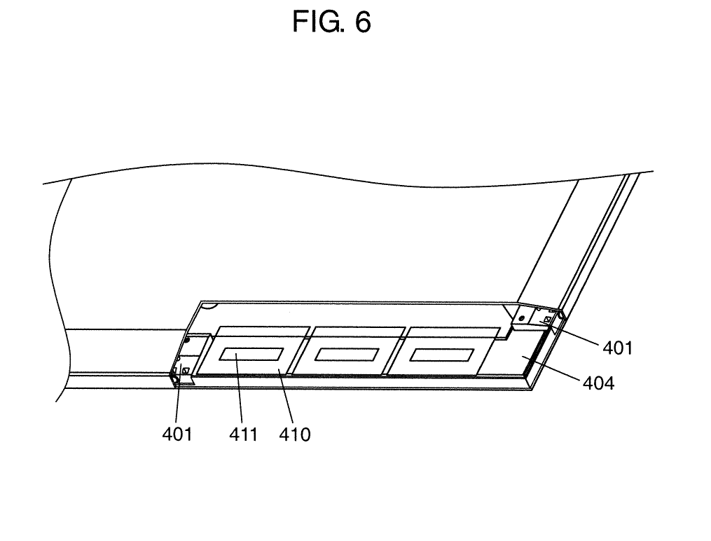

As shown in FIG. 6, organic EL display device 500 includes a plurality of FPCs (Flexible Printed Circuits) 410 that transmits a signal from a circuit board (not shown) to organic EL display panel 10. FPCs 410 are coupled with organic EL display panel 10 via an anisotropic conductive material, for example. Each of FPCs 410 includes driver IC 411. In organic EL display device 500 disclosed herein, FPCs 410 are disposed such that two or more number of the FPCs form one group, for example. Each of holding members 401 is disposed between the groups. This arrangement is intended to prevent physical interference between holding members 401 and FPCs 410.

In organic EL display device 500 disclosed herein, holding members 401 have enough mechanical strength to fix back cover 402 and escutcheon 403. This means that chassis 404 need not be provided with bosses or ribs. Moreover, there is no need for chassis 404 to have a large thickness enough for press-fitting of the bosses and to be subjected to deep drawing required for the press-fitting. Therefore, the thickness of chassis 404 can be made small, which allows organic EL display device 500 to be made compact in thickness.

Escutcheon 403 is coupled with holding members 401. Therefore, escutcheon 403 need not be provided with bosses that are necessary for coupling with chassis 404. This configuration allows a frame occupying an area outside of the display area can be made smaller. Moreover, since organic EL display panel 10 is not bonded to chassis 404, it results in improved workability of repair work. In addition, it also results in an improved efficiency of the heat radiation from organic EL display panel 10, leading to improved image quality.

It is noted, however, that the configuration described above is nothing more than an example. That is, the display device is not limited to organic EL display device 500. For example, the display device disclosed herein is applicable to other devices including liquid crystal display devices.

### 3. More Detailed Description of Organic EL Display Device 500

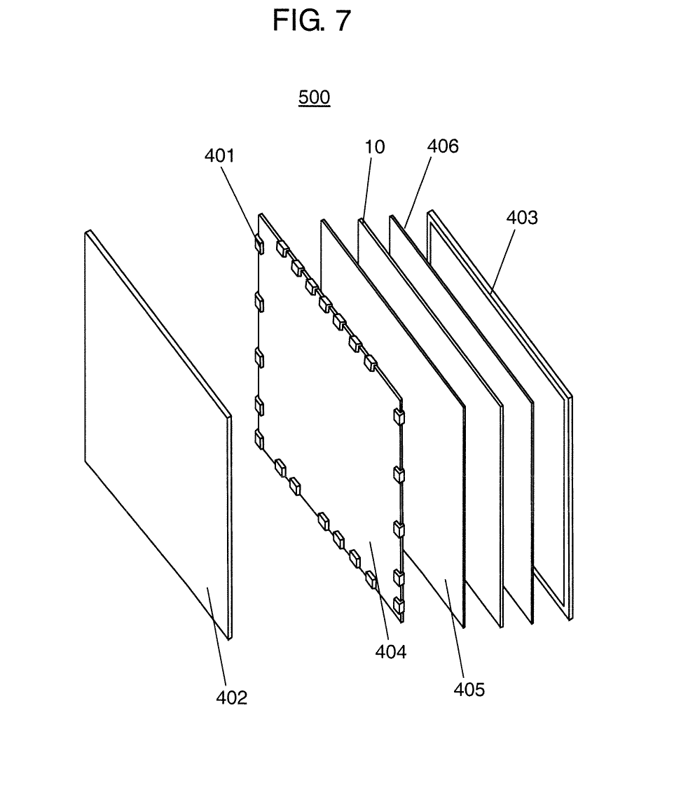

As shown in FIG. 7, organic EL display device 500 includes back cover 402, organic EL display panel 10 serving as an image display panel, chassis 404 disposed between back cover 402 and organic EL display panel 10, escutcheon 403 to cover the periphery of organic EL display panel 10, and the plurality of holding members 401. Holding members 401 may be disposed such that the holding members arranged at one side-edge of organic EL display device 500 are not necessarily equal in number to those arranged at the opposite side-edge of the display device. Moreover, holding members 401 may be not necessarily disposed at regular intervals. That is, the configuration is required only to provide mechanical strength enough to hold organic EL display panel 10. In chassis 404, a circuit board (not shown) is disposed on the back cover 402 side of the chassis. Organic EL display panel 10 is in contact with chassis 404 via heat radiation sheet 405. Antireflection sheet 406 may be disposed between escutcheon 403 and organic EL display panel 10.

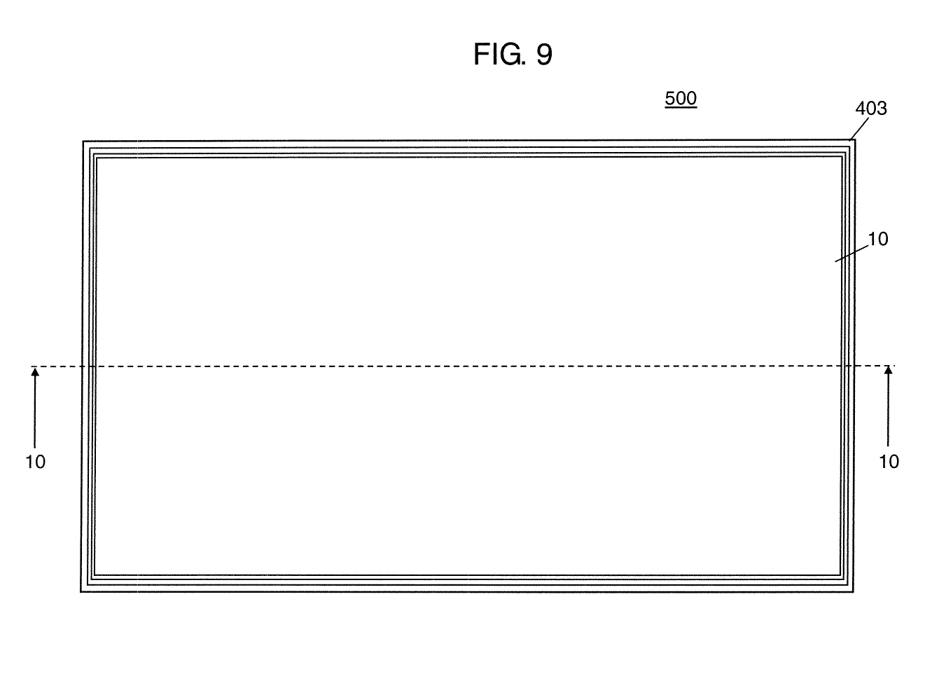

As shown in FIGS. 9 to 11, organic EL display device 500 according to the embodiment is of a rectangle having a short side of approximately 800 mm and a long side of approximately 1300 mm, as an example. The thickness of organic EL display device 500 becomes smaller from the center portion toward the peripheral portion thereof the minimum thickness is approximately 8 mm while the maximum thickness is approximately 15 mm. Moreover, the dimension of the frame is approximately 14 mm. It is noted, however, that the frame as referred herein means the width of escutcheon 403 as viewed from the display screen side.

The thickness of escutcheon 403 is approximately 0.5 mm. The thickness of organic EL display panel 10 is approximately 1.4 mm. The thickness of heat radiation sheet 405 is approximately 0.2 mm. The thickness of back cover 402 is approximately 0.5 mm. The thickness of each of holding members 401 is appropriately set in accordance with the distance between chassis 404 and back cover 402.

Chassis 404 is configured with an aluminum plate, as an example. In the embodiment, the major functions of chassis 404 are in that chassis 404 diffuses the heat locally generated from organic EL display panel 10 and that the heat generated from organic EL display panel 10 is dissipated to the outside via chassis 404. Consequently, chassis 404 is not required to have mechanical strength enough to hold organic EL display panel 10 only with chassis 404.

### 3-1. Assembly of Organic EL Display Device 500

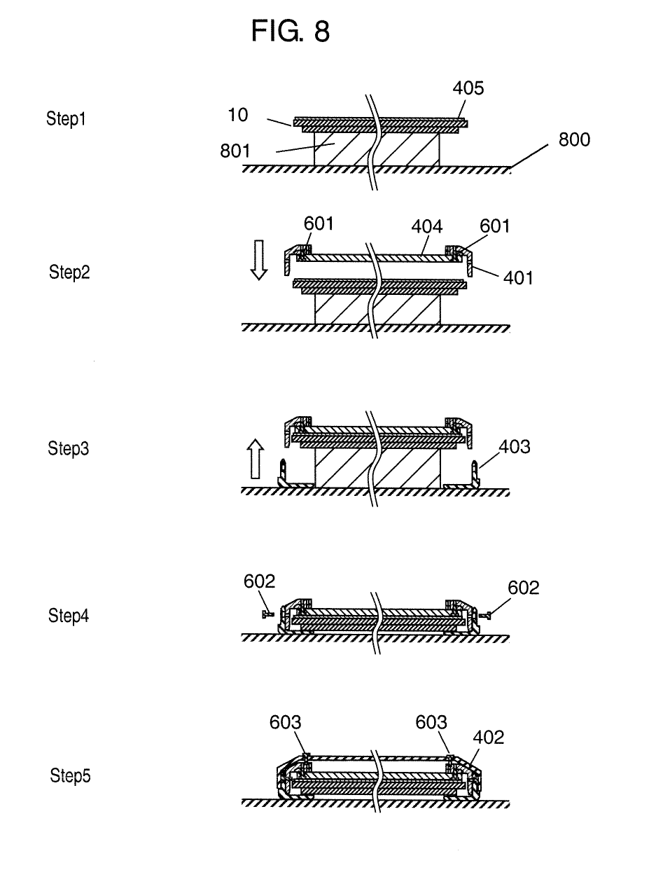

The assembling process of organic EL display device 500 includes Steps 1 to 5 shown in FIG. 8, as an example.

In Step 1, organic EL display panel 10 with heat radiation sheet 405 bonded thereto is placed, with the display screen of the panel facing downward. For convenience of assembling work, organic EL display panel 10 is placed on a cushioning material which is smaller in profile than organic EL display panel 10, as an example. The cushioning material is sponge 801, as an example. The cushioning material is placed on plate workbench 800, as an example.

In Step 2, chassis 404 with holding members 401 coupled therewith is placed on heat radiation sheet 405. In the embodiment, holding members 401 are coupled in advance with chassis 404 with first screw 601. Moreover, chassis 404 is not bonded to heat radiation sheet 405.

In Step 3, escutcheon 403 is attached from below organic EL display panel 10. Specifically, organic EL display panel 10 placed on sponge 801 is temporarily lifted from the sponge, followed by placing escutcheon 403 on the workbench. Then, organic EL display panel 10 is placed again on sponge 801. Next, escutcheon 403 is attached from below to organic EL display panel 10. Escutcheon 403 is subjected to an applied force such that a part of the inside of the escutcheon comes in contact with the periphery of organic EL display panel 10.

In Step 4, holding members 401 are coupled with escutcheon 403 with second screws 602. Accordingly, organic EL display panel 10 is held to be sandwiched between escutcheon 403 and chassis 404 coupled with holding members 401. Moreover, the periphery of organic EL display panel 10 is pushed by escutcheon 403 toward chassis 404.

In Step 5, back cover 402 is attached to cover the circumference of escutcheon 403. Back cover 402 is coupled with holding members 401 with third screws 603. Utilizing holding members 401 as structural cores, the cores are coupled with back cover 402, chassis 404, and escutcheon 403, which allows the structure to have the mechanical strength enough to hold organic EL display panel 10. That is, in organic EL display device 500 according to the embodiment, holding members 401, back cover 402, and escutcheon 403 are configured to provide the structure which sandwiches organic EL display panel 10 from both sides, i.e. the display screen side and the opposite side thereto. This configuration allows the mechanical strength enough to hold organic EL display panel 10.

In accordance with the assembling method described above, the resulting assembly can be easily checked for, such as, peeling of heat radiation sheet 405, by visual inspection from above workbench 800 or the like. Moreover, escutcheon 403 is fixed with the screws, with it being in place on workbench 800 due to the self weight of organic EL display device 500. Therefore, the assembling work can be performed with escutcheon 403 being prevented from deforming.

It is noted, however, that the view in FIG. 8 is different from the actual product in terms of horizontal and vertical reduction scales, for convenience of explanation.

### 3-2. Positional Relation of Holding Members 401 to Chassis 404, escutcheon 403, and back cover 402

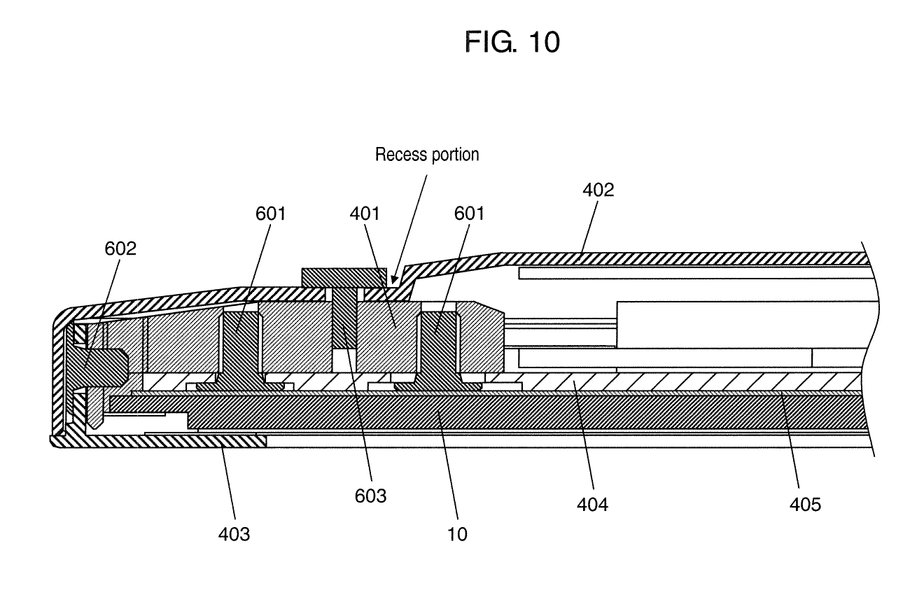

As shown in FIGS. 9 and 10, holding members 401 are each coupled with chassis 404 with first screw 601, as an example. First screw 601 is inserted into holding member 401 from the chassis 404 side. The number of first screw 601 may be two or more. The size of first screw 601 is M2, as an example.

As an example, holding members 401 are each coupled with escutcheon 403 with second screw 602. Second screw 602 is inserted into holding member 401 from outside of the side surface of escutcheon 403. The number of second screw 602 may be two or more. The size of second screw 602 is M1.6, as an example.

As an example, holding members 401 are each coupled with back cover 402 with third screw 603. Third screw 603 is inserted into holding member 401 from the back cover 402 side. The number of third screw 603 may be two or more. The size of third screws 603 is M2, as an example. Back cover 402 may include recesses corresponding in shape to holding members 401, in the close vicinities of the locations where third screws 603 are inserted. With such the recesses, the contact area between back cover 402 and holding members 401 becomes larger, resulting in the more stable coupling between holding members 401 and back cover 402 with third screws 603.

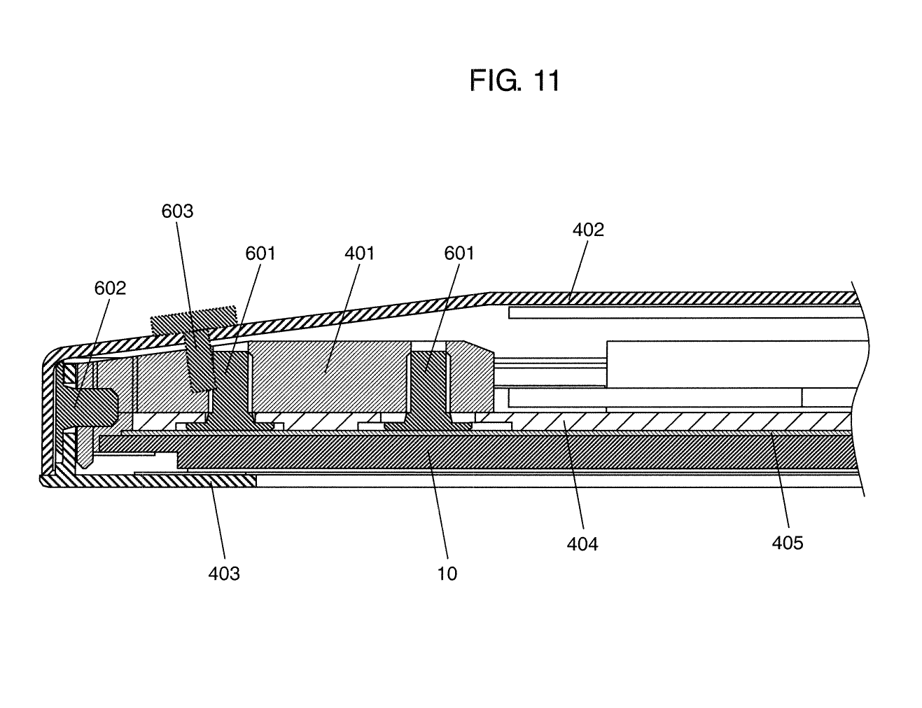

In the exemplary modification shown in FIG. 11, back cover 402 need not include recesses, depending on the locations where third screws 603 are attached. Specifically, third screws 603 are inserted where back cover 402 is inclined in accordance with the inclination of back cover 402. In FIG. 9, third screws 603 are disposed at positions out of the plane of the Figure in the depth direction. This means that third screws 603 are disposed at the positions without any physical interference with first screws 601.

### 3-3. Arrangement and Shape of Holding Members 401

As shown in FIGS. 4 and 7, holding members 401 are preferably disposed such that one or more of them are arranged at each of the two long and two short sides of organic EL display device 500. This arrangement is because, in organic EL display device 500, such the four-directional holding results in an increase in capability of holding the panel.

Moreover, holding members 401 are more preferably disposed such that two or more of them are arranged at each of the two long and two short sides of organic EL display device 500. This is because such the arrangement results in a further increased capability of holding organic EL display panel 10.

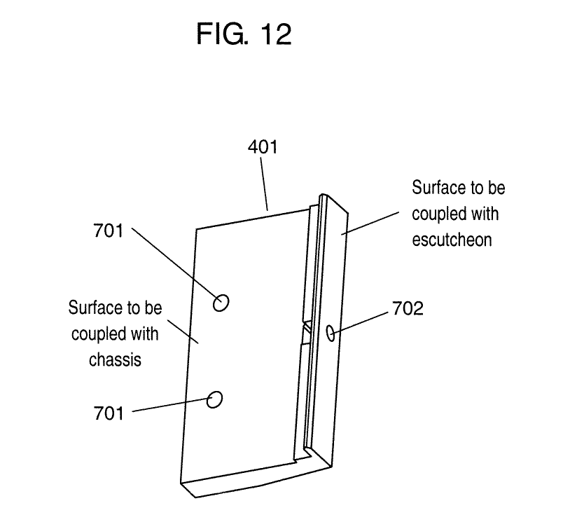

As shown in FIG. 12, each of holding members 401 disposed at each of the two long and two short sides of organic EL display device 500, has a surface to be coupled with chassis 404 and a surface to be coupled with escutcheon 403. The surface to be coupled with chassis 404 includes first threaded hole 701 into which first screw 601 is inserted. The surface to be coupled with escutcheon 403 includes second threaded hole 702 into which second screw 602 is inserted. It is noted, however, that the surface to be coupled with third screws 603 is not shown in the Figure.

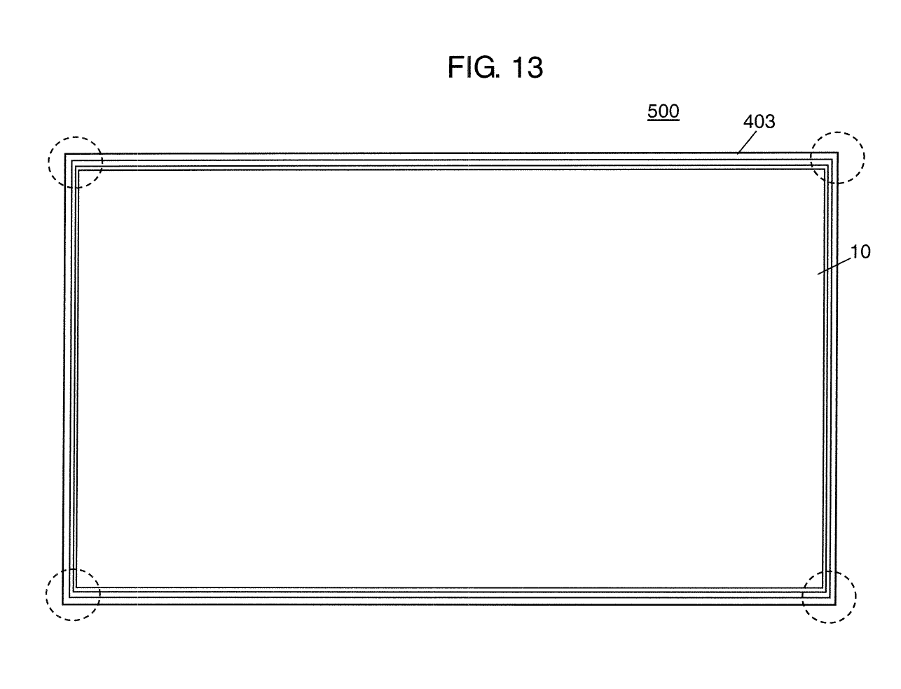

Moreover, holding members 401 may be disposed in corner portions of organic EL display device 500. As shown in FIG. 13, the corner portions of organic EL display device 500 are indicated by the dashed line circles. Holding members 401 disposed in the corner portions of organic EL display device 500 are capable of protecting the corner portions of organic EL display panel 10 in case organic EL display device 500 should be subjected to an external impact. Therefore, this allows a reduced possibility of breakages of organic EL display panel 10.

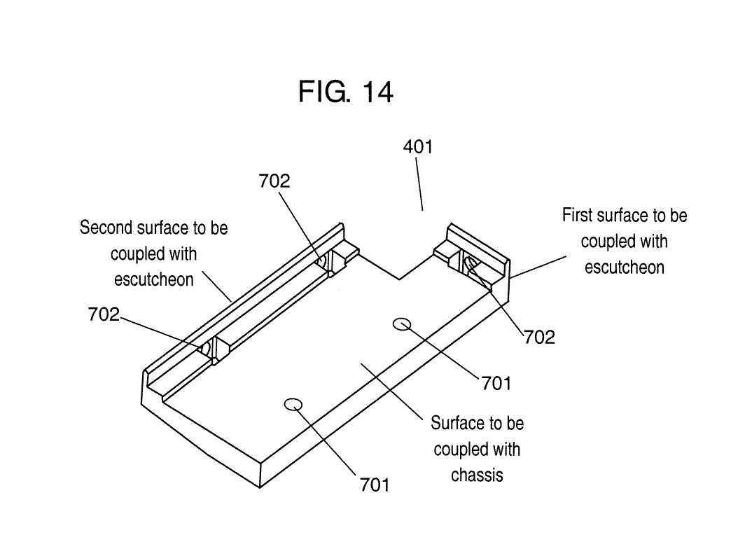

As shown in FIG. 14, each of holding members 401 disposed in the corner portions of organic EL display device 500, has a surface to be coupled with chassis 404, a first surface to be coupled with escutcheon 403, and a second surface to be coupled with escutcheon 403. The first and second surfaces correspond to the two sides that configure a corner portion of escutcheon 403. The surface to be coupled with chassis 404 includes first threaded hole 701 into which first screw 601 is inserted. Each of the first and second surfaces to be coupled with escutcheon 403 includes second threaded hole 702 into which second screw 602 is inserted. Moreover, the direction of second threaded hole 702 disposed in the first surface is perpendicular to that of second threaded hole 702 disposed in the second surface. That is, organic EL display panel 10 is held, by holding members 401 disposed in the corner portions, from the three directions that are perpendicular to each other. Therefore, this allows an increased capability of holding organic EL display panel 10.

### 4. Advantages and Others

Organic EL display device 500 according to the embodiment includes back cover 402, organic EL display panel 10 serving as an image display panel, chassis 404 disposed between back cover 402 and organic EL display panel 10, escutcheon 403 to cover the periphery of organic EL display panel 10, and the plurality of holding members 401. Each of the plurality of holding members 401 is coupled with chassis 404. Moreover, the each of the plurality of holding members 401 is coupled with escutcheon 403. In addition, at least a part of the plurality of holding members 401 is coupled with back cover 402. Organic EL display panel 10 is configured such that the periphery of organic EL display panel 10 is pushed, by escutcheon 403, in the direction toward chassis 404.

With the configuration described above, it is possible to reduce the thickness of organic EL display device 500 and to make the frame smaller.

That is, organic EL display device 500 according to the embodiment exhibits the mechanical strength enough to hold organic EL display panel 10 by taking the configuration in which organic EL display panel 10 is sandwiched from both the display screen side and the opposite side, through the use of holding members 401, back cover 402, and escutcheon 403. Accordingly, this configuration eliminates the need for bosses that are conventionally necessary to couple chassis 404 to back cover 402. Therefore, regions that are conventionally occupied by the bosses can be omitted.

Moreover, in accordance with the configuration described above, chassis 404 is not required to have mechanical strength enough to hold organic EL display panel 10 only with the chassis. This allows chassis 404 to be made smaller in thickness. Moreover, the dimensions of components associated structurally with holding members 401 can be designed in reference to holding members 401, which allows a reduction in the estimation of cumulative tolerance in organic EL display device 500. This, in turn, allows a smaller design margin of organic EL display device 500 in the thickness direction, resulting in the reduced thickness of organic EL display device 500.

Organic EL display device 500 according to the embodiment takes the configuration in which organic EL display panel 10 is sandwiched through the use of holding members 401, back cover 402, and escutcheon 403, which eliminates the need for bosses that are conventionally necessary to couple chassis 404 to escutcheon 403. Therefore, regions which are conventionally occupied by the bosses can be omitted.

Moreover, the dimensions of the components associated structurally with holding members 401 can be designed in reference to holding members 401, which allows a reduction in the estimation of cumulative tolerance in organic EL display device 500. This, in turn, allows a smaller design margin in width of the frame of organic EL display device 500, resulting in the reduced width of the frame of organic EL display device 500.

Furthermore, organic EL display panel 10 and chassis 404 need not be bonded to each other. This is because its repair work becomes easy in case a fault should occur in organic EL display panel 10 or the like.

It is noted, however, that organic EL display panel 10 and chassis 404 may be bonded to each other. This is because the bonding of them enhances the mechanical strength of organic EL display device 500.

As described above, the embodiments have been described as exemplary examples of the technology according to the present disclosure. To this end, the accompanying drawings and the detailed descriptions have been presented.

Consequently, among the elements set forth in the accompanying drawings and the detailed descriptions are possibly elements which are not essential for solving the problems, for purposes of exemplary illustration of the technology. It should not be acknowledged that these inessential elements are considered to be essential on the grounds that these inessential elements are set forth in the accompanying drawings and the detailed descriptions.

Moreover, the embodiments described above are intended only to exemplify the technology according to the present disclosure. Consequently, it is to be understood that various modifications, replacements, additions, omissions, and the like may be made to the embodiments without departing from the scope of the appended claims or the scope of their equivalents.

### INDUSTRIAL APPLICABILITY

As described above, the technology disclosed in the embodiments is applicable to large-screen display devices and the like.

### REFERENCE MARKS IN THE DRAWINGS

110 glass substrate
111 semiconductor layer
120 first insulating layer
130 first electrode
140 protective layer
141 first protective layer
142 second protective layer
150 second electrode
151 lower-layer electrode
152 upper-layer electrode
161 second insulating layer
170 TFT part
171 switching TFT
172 driving TFT
180 gate wiring
190 source wiring
200 EL device part
201 planarization layer
210 anode
211 lower-layer anode
212 upper-layer anode
220 bank
231 hole injection layer
232 electron blocking layer
240 light emitting layer
241 red-light emitting layer
242 green-light emitting layer
243 blue-light emitting layer
251 electron injection layer
260 cathode
271 sealing layer
300 color filter substrate
310 glass substrate
320 filter
321 red color filter
322 green color filter
323 blue color filter
401 holding member
402 back cover
403 escutcheon
404 chassis
405 heat radiation sheet
406 antireflection sheet
407 cushion
410 FPC
411 driver IC
500 organic EL display device
601 first screw
602 second screw
603 third screw
701 first threaded hole
702 second threaded hole
800 workbench
801 sponge

1. A display device comprising:
a back cover;
an image display panel;
a chassis disposed between the back cover and the image display panel;
an escutcheon covering a periphery of the image display panel; and
a plurality of holding members,
wherein each of the plurality of the holding members is coupled with the chassis, the each of the plurality of the holding members is coupled with the escutcheon, at least a part of the plurality of the holding members is coupled with the back cover, and the periphery of the image display panel is pushed by the escutcheon in a direction toward the chassis.

2. The display device according to claim 1, wherein the image display panel is not bonded to the chassis.

3. The display device according to claim 2, wherein the image display panel includes a heat radiation sheet on a chassis side.

4. The display device according to claim 3, further comprising an antireflection sheet disposed between the escutcheon and the image display panel for covering a display area of the image display panel.

5. The display device according to claim 4, wherein the image display panel has a shape in which a center portion of the panel is curved toward the chassis, as viewed from a display screen side.

6. The display device according to claim 1, wherein the image display panel is bonded to the chassis.

7. The display device according to claim 6, wherein the image display panel includes a heat radiation sheet on a chassis side.

8. The display device according to claim 7, further comprising an antireflection sheet disposed between the escutcheon and the image display panel for covering a display area of the image display panel.

9. The display device according to claim 1, wherein the image display panel is an organic EL panel including:
a TFT substrate;
an EL device part having a light emitting layer that emits light through recombination of holes and electrons; and
a color filter substrate.
